(19) United States
(12) Patent Application Publication
(10) Pub. No.: US 2010/0065900 A1
(43) Pub. Date: Mar. 18, 2010

(54) SEMICONDUCTOR DEVICE INCLUDING RESISTANCE ELEMENT

(76) Inventors: Takeshi MURATA, Kawasaki-shi (JP); Takeshi Kamigaichi, Yokohama-shi (JP); Itaru Kawabata, Yokohama-shi (JP); Shinya Takahashi, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/560,783

(22) Filed: Sep. 16, 2009

(30) Foreign Application Priority Data
Sep. 17, 2008 (JP) 2008-238327

(51) Int. Cl. H01L 29/8605; H01L 29/792; H01L 23/48

(52) U.S. Cl. 257/314; 257/536; 257/773; 257/E29.326; 257/E27.101; 257/E23.011

(57) ABSTRACT

A semiconductor device includes a resistance element. The resistance element includes a first and second conductive films, second insulating film, and contact plugs. The first conductive film is formed on a semiconductor substrate with a first insulating film interposed therebetween. The second insulating film is formed on the first conductive film. The second conductive film is formed on the second insulating film. In the first connection portion, the second insulating film is removed. The first connection portion connects the first conductive film and the second conductive film together. The contact plugs are formed on the second conductive film. The contact plugs are arranged such that a region located on the second conductive film and immediately above the connection portion is sandwiched between the contact plugs.

### CROSS-REFERENCE TO RELATED APPLICATIONS

This application is based upon and claims the benefit of priority from prior Japanese Patent Application No. 2008-238327, filed Sep. 17, 2008, the entire contents of which are incorporated herein by reference.

### BACKGROUND OF THE INVENTION

1. Field of the Invention

The present invention relates to a semiconductor device.

2. Description of the Related Art

EEPROMs (Electrically Erasable and Programmable Read Only Memories) are conventionally known as nonvolatile semiconductor memories. A memory cell in an EEPROM normally has a MISFET structure including a stacked gate with a charge accumulation layer and a control gate stacked on a semiconductor substrate.

The conventional EEPROM uses a technique in which resistance elements and MOS transistors provided in a peripheral circuit controlling operations are configured similarly to memory cells. Such a technique is disclosed in, for example, Jpn. Pat. Appln. KOKAI Publication No. 2006-339241.

For example, resistance element has a conductive layer as a charge accumulation layer for a memory cell used as a resistor portion. And the resistance element has a conductive layer as a control gate is used as an electrode portion. In this case, an insulating film between the two conductive layers needs to be removed in order to connect the resistor portion and the electrode portion together. The insulating film functions as an inter-gate insulating layer between the charge accumulation layer and control gate in the memory cell. The resistance element configured as described above is connected to a metal wiring layer via a contact plug.

### BRIEF SUMMARY OF THE INVENTION

A semiconductor device according to an aspect of the present invention includes:

a resistance element including:
a first conductive film formed on a semiconductor substrate with a first insulating film interposed therebetween and performing as a resistor portion of the resistance element;
a second insulating film formed on the first conductive film;
a second conductive film formed on the second insulating film;
a first connection portion in which the second insulating film is removed and which connects the first conductive film and the second conductive film together; and
a plurality of contact plugs formed on the second conductive film, the plurality of contact plugs being arranged such that a region located on the second conductive film and immediately above the connection portion is sandwiched between the contact plugs.

### BRIEF DESCRIPTION OF THE SEVERAL VIEWS OF THE DRAWING

FIG. 1 is a block diagram of a flash memory according to a first embodiment of the present invention;

FIG. 2 is a plan view of a memory cell array according to the first embodiment;

FIG. 3 to FIG. 5 are sectional views taken along lines 3-3, 4-4, and 5-5, respectively, in FIG. 2;

FIG. 6 is a plan view of a resistance element according to the first embodiment;

FIG. 7 and FIG. 8 are sectional views taken along lines 7-7 and 8-8, respectively, in FIG. 6;

FIG. 9A and FIG. 9B are a plan view and a sectional view of a select transistor and a resistance element according to the first embodiment;

FIG. 10, FIG. 12, FIG. 14, FIG. 16, FIG. 18, FIG. 20, FIG. 22, FIG. 24, and FIG. 26 are sectional views of a first step to a ninth step of manufacturing the memory cell array according to the first embodiment;

FIG. 11, FIG. 13, FIG. 15, FIG. 17, FIG. 19, FIG. 21, FIG. 23, FIG. 25, and FIG. 27 are sectional views of a first step to a ninth step of manufacturing the resistance element according to the first embodiment;

FIG. 28A to FIG. 28E and FIG. 29A to FIG. 29F are plan views of an electrode portion in the resistance element according to a second embodiment of the present invention; and

FIG. 30 is a sectional view of a memory cell array, a resistance element, and a peripheral transistor according to a modification of the first and second embodiments.

### DETAILED DESCRIPTION OF THE INVENTION

Embodiments of the present invention will be described below with reference to the drawings. In the description below, common components throughout the drawings are denoted by the same reference numerals. The drawings are schematic. It should be noted that the relationship between thickness and planar dimensions and the ratio of thicknesses of layers, and the like are different from real ones.

### First Embodiment

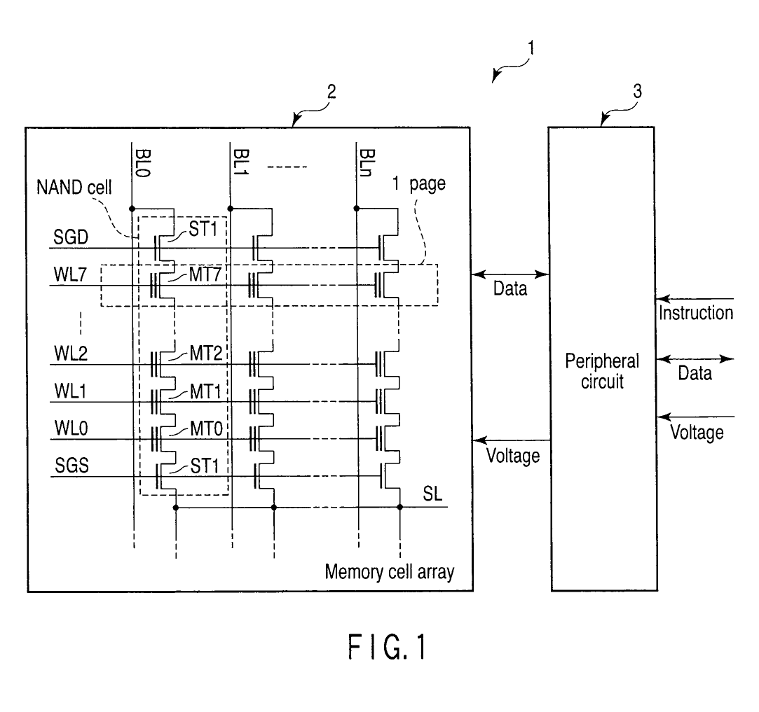

A semiconductor device according to a first embodiment of the present invention will be described with reference to FIG. 1. FIG. 1 is a block diagram showing a part of the configuration of a NAND flash memory according to the present embodiment.

As shown in FIG. 1, a NAND flash memory 1 includes a memory cell array 2 and a peripheral circuit 3. First, the configuration of the memory cell array 2 will be described.

### <Configuration of the Memory Cell Array 2>

<Circuit Configuration>

As shown in FIG. 1, the memory cell array 2 has a plurality of NAND cells. FIG. 1 shows only NAND cells in one row. Each of the NAND cells includes, for example, eight memory cell transistors MT0 to MT7 and select transistors ST1 and ST2. For simplification of description, when not distinguished from one another below, the memory cell transistors MT0 to MT7 are simply referred to as a memory cell transistor MT. The memory cell transistor MT includes a stacked gate structure having a charge accumulation layer (for example, a floating gate) formed on a semiconductor substrate with a gate insulating film interposed therebetween and a control gate formed on the floating gate with an inter-gate insulating film interposed therebetween. The number of memory cell transistors MT is not limited to 8 but may be 16, 32, 64, 128, or 256; no limit is imposed on the number of memory cell transistors MT. The adjacent memory cell transistors MT share a source and a drain. The memory cell transistors MT are arranged between select transistors ST1 and ST2 so that current paths in the respective memory cell transistors MT are connected in series. A drain region of one of the series-connected memory cell transistors MT located at one end of the array of the memory cell transistors MT is connected to a source region of the select transistor ST1. A source region of one of the series-connected memory cell transistors MT located at the other end of the array of the memory cell transistors MT is connected to a drain region of the select transistor ST2. Each of the select transistors ST1 and ST2 has a stacked gate structure similarly to the memory cell transistor MT. However, in the select transistors ST1 and ST2, an inter-gate insulating film is removed from a partial region to electrically connect a lower gate and an upper gate of the stacked gate structure together.

Control gates of the memory cell transistors MT in the same row are connected to one of word lines WL0 to WL7 in common. Gates of the select transistors ST1 in the same row are connected to a select gate line SGD in common. Gates of the select transistors ST2 in the same row are connected to a select gate line SGS in common. Although not shown in FIG. 1, a plurality of NAND cells are arranged orthogonally to the word lines WL0 to WL7. Drains of the select transistors ST1 in the same column are connected to one of bit lines BL0 to BLn (n is a natural number) in common. For simplification of description, when not distinguished from one another below, the word lines WL0 to WL 31 and the bit lines BL0 to BLn are simply referred to as a word line WL and a bit line BL, respectively. Sources of the select transistors ST2 are all connected to a source line SL in common. Both select transistors ST1 and ST2 are not required. One of the select transistors ST1 and ST2 may be omitted provided that any of the NAND cells can be selected.

In the above-described configuration, data is written at a time to the memory cell transistors MT connected to the same word line WL. This unit is called one page. Moreover, data is erased from a plurality of NAND cells at a time. This unit is called a block. The block is formed of a set of a plurality of NAND cells in the same row, that is, a set of NAND cells connected to the same word line WL or the same select gate line SGD or SGS.

<Planar Configuration>

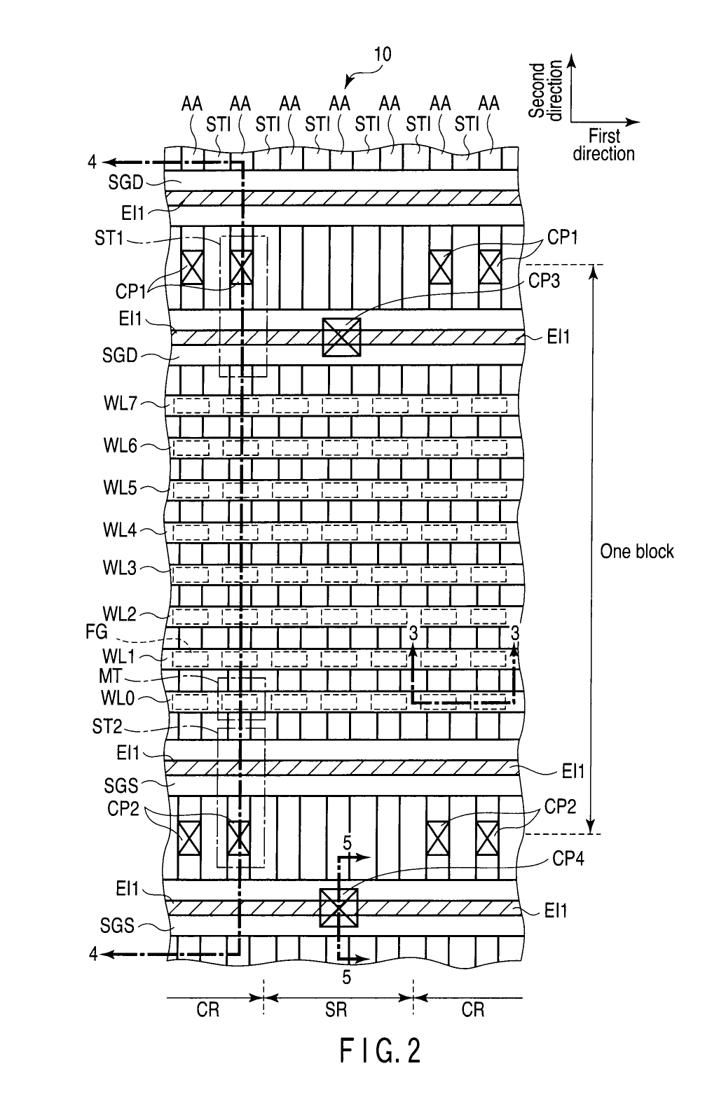

Now, the planar configuration of the memory cell array 2 configured as described above will be described with reference to FIG. 2. FIG. 2 is a plan view of the memory cell array 2.

As shown in FIG. 2, the memory cell array 2 includes cell regions CR in each of which the NAND cell holding data is formed, and shunt regions SR in each of which the gate of the select transistor ST1 or ST2 is connected to a shunt wire. The cell regions CR and the shunt regions SR are alternately arranged along a first direction in a semiconductor substrate surface.

A plurality of element regions AA are provided in stripe form along a second direction orthogonal to the first direction in the cell regions CR and shunt regions SR in a semiconductor substrate 10. An element isolation region STI is formed between the adjacent element regions AA. The element regions AA are electrically separated from each other by the element isolation region STI.

The word lines WL and select gate lines SGD and SGS extending along the first direction in stripe form are formed on the semiconductor substrate 10 so as to cross a plurality of the element regions AA in the cell regions CR and shunt regions SR. In the cell region CR, a charge accumulation layer (floating gate FG) is provided in a region in which the word line WL crosses the element region AA. The memory cell transistor MT is provided in the region in which the word line crosses the element region AA. The select transistors ST1 and ST2 are provided in regions in which the select gate lines SGD and SGS, respectively, cross the element region AA. An impurity diffusion layer serving as the source region or drain region of the memory cell transistor MT and the select transistors ST1 and ST2 is formed in the element region AA between the adjacent word lines WL, between the adjacent select gate lines, and between the word line and the adjacent select gate line, in the first direction. A configuration similar to that in the cell region is also provided in the shunt region SR. However, the configuration in the shunt region SR does not function as the memory cell transistor MT or the select transistor ST1 or ST2.

The impurity diffusion layer formed in the element region AA between the adjacent select gate lines SGD functions as a drain region of the select transistor ST1. A contact plug CP1 is formed on the drain region. The contact plug CP1 is connected to the bit lines BL (not shown in the drawings) extending along the second direction in stripe form. The impurity diffusion layer formed in the element region AA between the adjacent select gate lines SGS functions as the source region of the select transistor ST2. A contact plug CP2 is formed on the source region. The contact plug CP2 is connected to a source line SL (not shown in the drawings).

A connection portion EI (Etching Inter-poly) 1 is provided on each of the select gate lines SGD and SGS.

The connection portion EI1 corresponds to a region of the stacked gate structure of each of the select transistors ST1 and ST2 in which region the inter-gate insulating film is removed. The upper gate and the lower gate are connected together via the connection portion EI1. The connection portion EI1 has, for example, a rectangular shape with a longitudinal direction extending along the first direction.

In the shunt region SR, contact plugs CP3 and CP4 connected to the select gate lines SGD and SGS, respectively, are provided. Also in the shunt region SR, the connection portion EI1 is continuously provided. Thus, the contact plugs CP3 and CP4 are provided on the connection portions EI1 of the select gate lines SGS and SGS, respectively. The contact plugs CP3 and CP4 are connected to shunt wires (not shown in the drawings). The shunt wire allows row-direction select signals provided by a row decoder to be transmitted. The shunt wire is formed of a wiring layer with a resistance lower than that of the stacked gate structure of each of the stacked transistors ST1 and ST2. The stacked transistors ST1 and ST2 can be performed at a high-speed by providing select signal transmitted through the shunt wire to the stacked gate structure of each of the select transistors ST1 and ST2 in the shunt region SR.

Furthermore, for example, regarding a certain block, the contact plugs CP3 and CP4 are alternately provided along the first direction. That is, in the certain shunt region SR, the contact plug CP3 is provided and not the contact plug CP4. The shunt region SR adjacent to the certain shunt region SR includes the contact plug CP4 and not the contact plug CP3.

<Sectional Configuration>

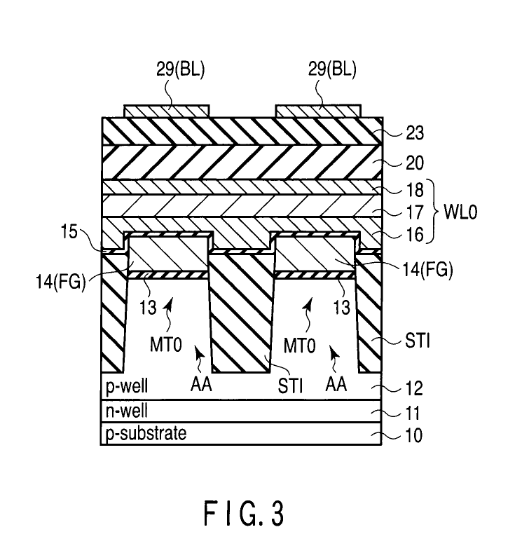

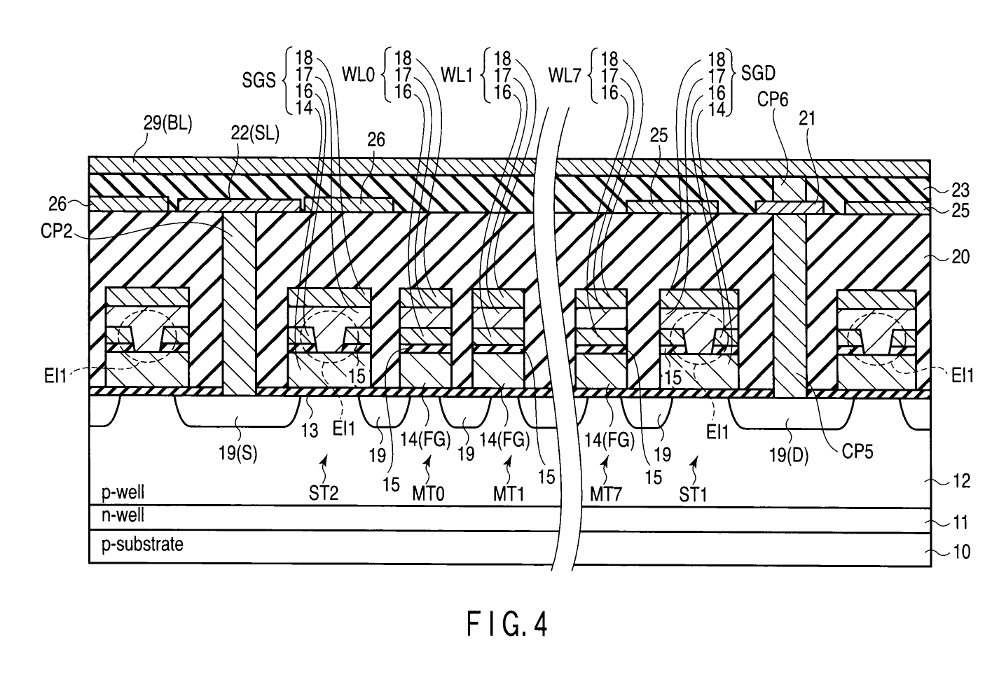

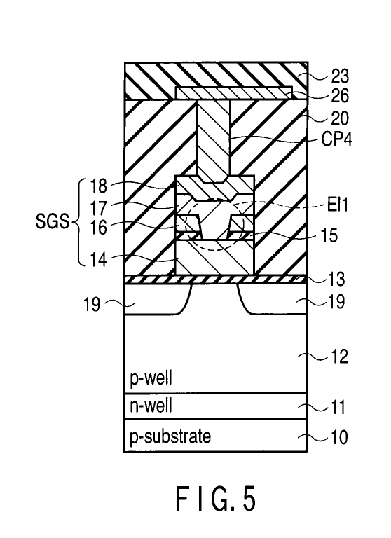

Now, the sectional configuration of the NAND cell configured as described above will be described with reference to FIG. 3 to FIG. 5. FIG. 3 to FIG. 5 are sectional views taken along line 3-3 (first direction), line 4-4 (second direction), and line 5-5 (second direction; the contact plug on the connection portion) in FIG. 2.

As shown in the figures, an n-type well region 11 is formed in the surface region of the p-type semiconductor substrate 10. A p-type well region 12 is formed in the surface region of the n-type well region 11. A plurality of the element isolation regions STI are formed in the surface of the n-type region 11 in stripe form. The element isolation region STI is formed of a trench formed in the well region 12 and an insulating film filled into the trench. The region between the adjacent element isolation regions STI corresponds to the element region AA.

A gate insulating film 13 is formed on a part of the well region 12 corresponding to the element region AA. The gate electrodes of the memory cell transistors MT and the select transistors ST1 and ST2. Each of the gate electrode includes a polycrystalline silicon layer 14 formed on the gate insulating film 13, an inter-gate insulating film 15 formed on the polycrystalline silicon layer 14, and polycrystalline silicon layers 16 and 17 and a silicide layer 18 formed on the inter-gate insulating film 15. The inter-gate insulating film 15 is formed of, for example, a silicon oxide film, or an ON film, an NO film, an ONO film, or an ONON film each of which is a stacked structure of silicon oxide films and silicon nitride films, or a stacked structure including any of the above-described stacked structures, or a stacked structure of a TiO₂ film, an HfO₂ film, an Al₂O₃ film, an HfAlOₓ film, or an HfAlSi film and a silicon oxide film or a silicon nitride film. Furthermore, the gate insulating film 13 of the memory cell transistor MT functions as a tunnel insulating film.

In the memory cell transistor MT, the polycrystalline silicon layer 14 is divided into parts corresponding to the respective memory cell transistors MT in the first direction and functioning as charge accumulation layers (for example, floating gates FG). On the other hand, the adjacent polycrystalline silicon layers 16 in the first direction are connected together. The adjacent polycrystalline silicon layers 17 in the first direction are connected together. The adjacent silicide layers 18 in the first direction are connected together. The connected polycrystalline silicon layers 16 and 17 and the silicide layer 18 function as a control gate (word line WL). That is, the polycrystalline silicon layers 16 and 17 and the silicide layer 18 are formed to extend across the element isolation region STI and over a plurality of the element regions AA. The top surface of the element isolation region STI is formed to be lower than that of the polycrystalline silicon layer 14. The inter-gate insulating film 15 is also formed on the side surface of a region of the polycrystalline silicon layer 14 projecting from the surface of the element isolation region STI.

In each of the select transistors ST1 and ST2, the adjacent polycrystalline silicon layers 14 in the direction of the word lines are connected together. The adjacent polycrystalline silicon layers 16 in the direction of the word lines are connected together. The adjacent polycrystalline silicon layers 17 in the direction of the word lines are connected together. The adjacent silicide layers 18 in the direction of the word lines are connected together. The connected polycrystalline silicon layers 14, 16, and 17 and the connected silicide layers 18 function as the select gate line SGS or SGD. In each of the select transistors ST1 and ST2, the connection portion EI1 includes an opening region made by removing parts of the inter-gate insulating film 15 and the polycrystalline silicon film 16. The polycrystalline silicon layers 14, 16, and 17 are connected together via the connection portion EI1.

Each of the select gate lines SGD and SGS in the shunt region has a structure similar to that of each of the select transistors ST1 and ST2 except that in each of the select gate lines SGD and SGS, the contact plug CP3 or CP4, respectively, is connected to the silicide layer 18 on the connection portion EI1.

An n-type impurity diffusion layer 19 is formed in the surface of the well region 12, located between the gate electrodes. The impurity diffusion layer 19 is shared by the adjacent transistors and functions as a source (S) or a drain (D). Furthermore, the region between the source and the drain functions as a channel region through which electrons migrates. The gate electrodes, the impurity diffusion layer 19, and the channel region form each of the MOS transistors serving as the memory cell transistors MT and select transistors ST1 and ST2.

An interlayer insulating film 20 is formed on the semiconductor substrate 10 so as to cover the memory cell transistors MT and select transistors ST1 and ST2. The contact plug CP2 is formed in the interlayer insulating film 20 so as to reach the impurity diffusion layer (source) 19 in the source-side select transistor ST2. A metal wiring layer 22 is formed on the interlayer insulating film 20 so as to connect to the contact plug CP2. The metal wiring layer 22 functions as the source line SL. Furthermore, a contact plug CP5 is formed in the interlayer insulating film 20 so as to reach the impurity diffusion layer (drain) 19 in the drain-side select transistor ST1. A metal wiring layer 21 is formed on the interlayer insulating film 20 so as to connect to the contact plug CP5. Moreover, the contact plugs CP3 and CP4 are formed in the interlayer insulating film 20 so as to reach the gate electrodes (silicide layer 18) of the select transistors ST1 and ST2. Metal wiring layers 25 and 26 are formed on the interlayer insulating film 20 so as to connect to the contact plugs CP3 and CP4.

An interlayer insulating film 23 is formed on the interlayer insulating film 20 so as to cover the metal wiring layers 21, 22, 25, and 26. A contact plug CP6 is formed in the interlayer insulating film 23 so as to reach the metal wiring layer 21. Metal wiring layers 29 are formed on the interlayer insulating film 23 in stripe form along the second direction so as to connect to a plurality of the contact plugs CP6. The metal wiring layer 29 is formed on the interlayer insulating film 23 immediately above the element region AA. The metal wiring layer 29 functions as the bit line BL. The contact plugs CP5 and CP6 and the metal wiring layer 21 correspond to the contact plug CP1 in FIG. 2.

### <Configuration of the Peripheral Circuit 3>

Now, the peripheral circuit 3 will be described. In accordance with externally provided instructions, the peripheral circuit 3 transmits and receives data to and from the memory cell array 2 and provides a voltage to the memory cell array 2. The peripheral circuit 3 includes, for example, a row decoder, a sense amplifier, a voltage generation circuit, and a sequencer.

During a data write operation, a data read operation, and a data erase operation, based on an externally provided row address RA, the row decoder applies voltages to the select gate lines SGD and SGS and word lines WL connected to the corresponding block. As described above, the voltages provided to the select gate lines SGD and SGS are also transmitted through the shunt wires 25 and 26.

During the data read, the sense amplifier senses and amplifies data read from the memory cell transistor MT onto the bit line BL. The sense amplifier senses a current flowing through the bit line BL to determine the read data. Alternatively, the sense amplifier senses the voltage of the bit line BL. During the data write, the sense amplifier transfers write data to the bit line BL.

For example, during the data write, the voltage generation circuit generates a voltage to be applied to the word line WL. The voltage generation circuit includes a resistance element that reduces the voltage and a charge pump circuit that increases the voltage.

During the data write operation, the data read operation, and the data erase operation, the sequencer performs a required operational sequence to control the operations of the row decoder, the sense amplifier, and the voltage generation circuit.

The configuration of the resistance element included in the peripheral circuit 3 will be described below. The resistance element can be used, for example, to reduce the voltage as described above. Of course, the application of the resistance element is not limited to this aspect and can be used for any of various applications in the peripheral circuit 3.

<Planar Configuration of the Resistance Element>

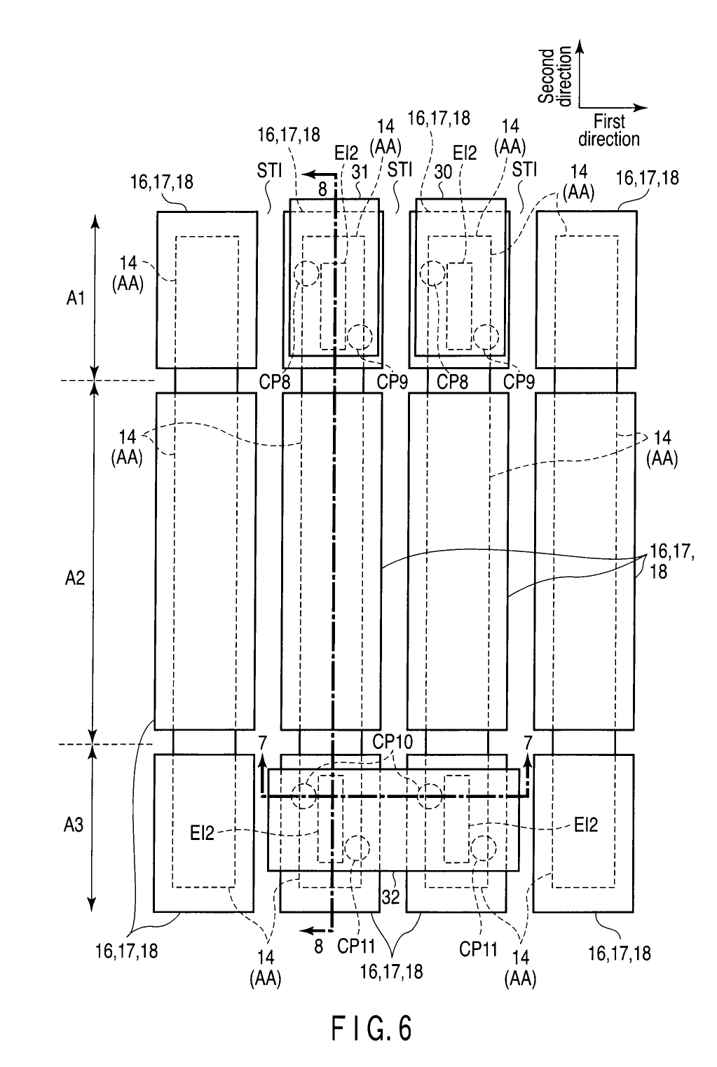

The planar configuration of the resistance element will be described with reference to FIG. 6. FIG. 6 is a plan view of the resistance element. The resistance element is formed on the same semiconductor substrate 10 on which the memory cell array of the above-described NAND flash memory is provided.

FIG. 6 shows that two resistance elements are connected in series. First ends of the two resistance elements are connected to metal wiring layers 30 and 31, respectively. Second ends of the resistance elements are connected to a common metal wiring layer 32. That is, the two resistance elements are connected in series between the two metal wiring layers 30 and 31. The potential difference between the two metal wiring layers 30 and 31 is divided into two equal voltages by the two resistance elements so that the resulting voltages can be obtained from the metal wiring layer 32. FIG. 6 shows that the two resistance elements divide the voltage between the metal wiring layers 30 and 31 into equal voltages. However, of course, the voltage ratio can be changed based on the number of resistance elements and the resistance value of each of the resistance elements.

As shown in FIG. 6, for example, four element regions AA extending in the second direction in stripe form are formed in the semiconductor substrate 10 along the first direction, which is orthogonal to the second direction. The terms “first and second directions” in the present example are for convenience of description only and may be different from or the same as the first and second directions in FIG. 2, respectively.

The resistance element is formed on the element region AA. In FIG. 6, only the resistance elements formed on two central element regions AA of the four element regions AA function as actual resistance elements. The two outer resistance elements are dummies. For simplification of description, the elements serving as dummies are hereinafter referred to as “dummy elements”. The elements actually functioning as resistance elements are hereinafter referred to as “resistance elements”. That is, the two resistance elements extending along the second direction in stripe form are sandwiched between the two dummy elements in the first direction. Of course, the number of resistance elements sandwiched between the dummy elements may be two or more. The dummy elements have the same configuration as that of the resistance elements. Thus, the configuration of the resistance elements will be described below. However, both elements have the same configuration unless otherwise specified.

The polycrystalline silicon layer 14, functioning as the resistor portion of the resistance element, is formed on the element region AA. In FIG. 6, the element region AA and the polycrystalline silicon layer 14 have the same planar pattern and are thus both denoted by reference numeral “14(AA)”. The polycrystalline silicon layers 16 and 17 and the silicide layer 18 are formed on the polycrystalline silicon layer 14 via an insulating film (not shown in the drawings). The polycrystalline silicon layers 16 and 17 and the silicide layer 18 are each divided into three regions A1, A2, and A3 along the second direction. The regions A1 and A3 are located at the opposite ends of the resistance element along the second direction. The region A2 is located in the center of the resistance element sandwiched between the regions A1 and A3. The polycrystalline silicon layer 14 in the regions A1 to A3 functions substantially as a resistance element (the layer 14 is hereinafter referred to as a resistor portion). On the other hand, the polycrystalline silicon layers 16 and 17 and silicide layer 18 in the regions A1 and A3 function as regions in which the resistor portion is connected to the wires 30 to 32 (these regions are hereinafter referred to as an electrode portion).

In the electrode portion, the insulating film 15 is partly removed to form a connection portion EI2.

The resistor portion and electrode portion of the resistance element are connected together via the connection portion EI2. The connection portion EI2 has, for example, a rectangular shape with a longitudinal direction extending along the second direction.

Two contact plugs CP8 and CP9 are provided on the electrode portion in the region A1. The electrode portion is connected to the metal wiring layer 30 or 31 via the contact plugs CP8 and CP9. Furthermore, two contact plugs CP10 and CP11 are provided on the electrode portion in the region A3. The electrode portion is connected to the metal wiring layer 32 via the contact plugs CP10 and CP11.

<Sectional Configuration>

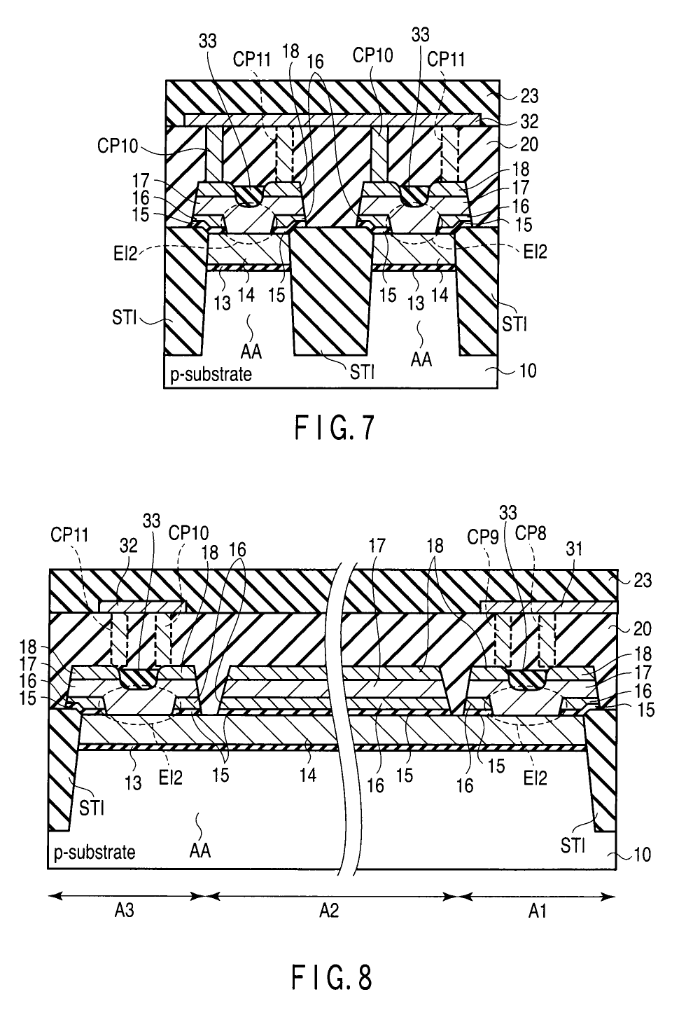

Now, the sectional configuration of the above-described resistance elements will be described with reference to FIG. 7 and FIG. 8. FIG. 7 and FIG. 8 are sectional views taken along lines 7-7 and 8-8 in FIG. 6.

As shown in FIG. 7 and FIG. 8, a plurality of the element regions AA extending along the second direction in stripe form are formed in the surface of the semiconductor substrate 10. The element isolation regions STI are formed around the periphery of each of the element regions AA. The element isolation region STI is formed of a trench formed in the surface of the semiconductor substrate 10 and an insulating film filling the interior of the trench.

The polycrystalline silicon layer 14 is formed on the element region AA with the gate insulating film 13 interposed therebetween. The polycrystalline silicon layer 16 is formed on the polycrystalline silicon layer 14 with the inter-gate insulating film 15 interposed therebetween. The polycrystalline silicon layer 17 and the silicide layer 18 are sequentially formed on the polycrystalline silicon layer 16. As described above, in each of the element regions AA, each of the inter-gate insulating films 15, the polycrystalline silicon layers 16 and 17, and the silicide layer 18 is divided into three regions in the second direction (see FIG. 8). Trenches are formed between the regions A1 and A2 and between the regions A2 and A3 by removing appropriate parts of the polycrystalline silicon layers 16 and 17 and the silicide layer 18.

The above-described connection portion EI2 is formed in each of the regions A1 and A3. In the connection portion EI2, upper part of polycrystalline silicon 14, the inter-gate insulating film 15 and the polycrystalline silicon layer 16 are partly removed to form an opening. This allows the polycrystalline silicon layers 14 and 17 to be connected together. Because of the presence of the opening, the surface of the polycrystalline silicon layer 17 in the regions A1 and A3 is recessed, with the silicide layer 18 formed in the regions other than the recess. An insulating film, for example, a silicon nitride film 33 is formed in the recess.

The interlayer insulating film 20 is formed on the semiconductor substrate 10 so as to cover the above-described resistance elements. The contact plugs CP8 and CP9 are formed in the interlayer insulating film 20 so as to reach the silicide layer 18 in the region A1. The contact plugs CP10 and CP11 are formed in the interlayer insulating film 20 so as to reach the silicide layer 18 in the region A3. The metal wiring layers 30 to 32 are formed on the interlayer insulating film 20. The metal wiring layer 30 is connected to the contact plugs CP8 and CP9 in one of the two resistance elements. The metal wiring layer 31 is connected to the contact plugs CP8 and CP9 in the other resistance element. The metal wiring layer 32 is connected to the contact plugs CP10 and CP11 in the two resistance elements. That is, the metal wiring layer 32 electrically connects the two resistance elements together via the contact plugs CP10 and CP11.

In the above-described configuration, as described above, the polycrystalline silicon layer 14, linearly formed so as to cover the regions A1 to A3, is a region of the resistance element functioning substantially as a resistor. Furthermore, the polycrystalline silicon layers 16 and 17 and silicide layers 18 in the regions A1 and A3 function as electrodes in the resistance elements.

In the example shown in FIG. 6 to FIG. 8, the two resistance elements are arranged in parallel. However, the number of the resistance elements is not limited to two and may be one or three or more. Furthermore, the polycrystalline silicon layers 14, 16, and 17 and the silicide layer 18 have only to be conductive layers but are formed of the same material as that of the memory cell array described with reference to FIG. 2 to FIG. 4.

### <Arrangement of the Connection Portions E11 and EI2 and the Contact Plugs CP8 to CP11>

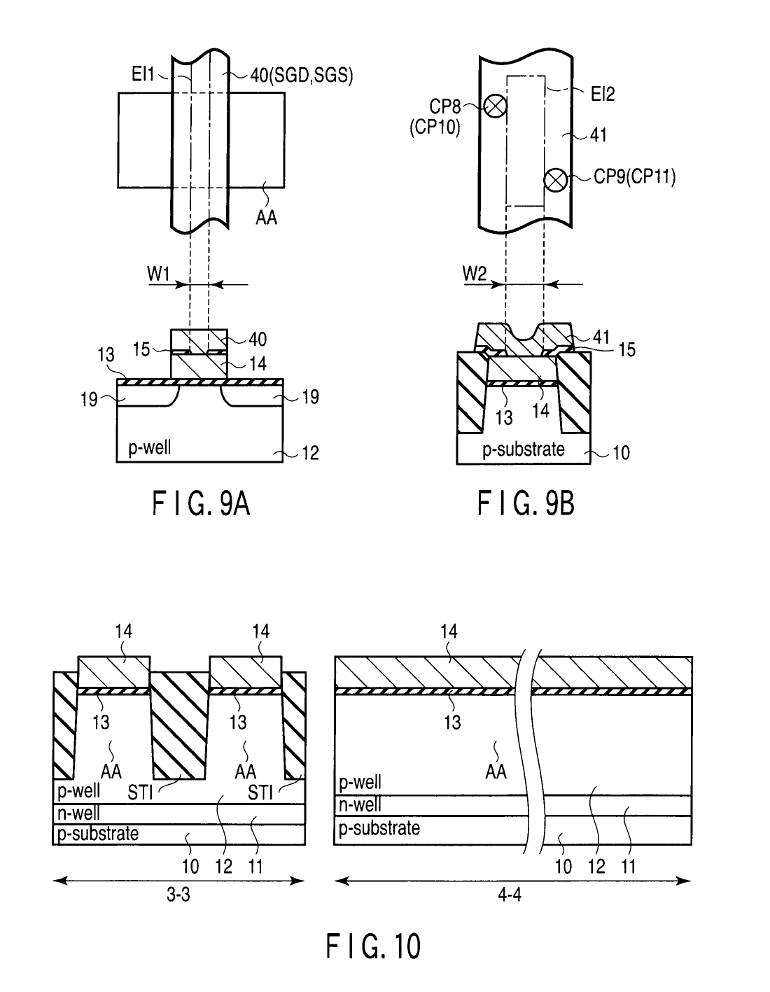

Now, the arrangement of the connection portions EI1 and EI2 and the contact plugs CP8 to CP11 will be described in detail with reference to FIG. 9A and FIG. 9B. FIG. 9A is a plan view of each of the select transistors ST1 and ST2 and a sectional view of each of the select transistors ST1 and ST2 taken along the second direction. FIG. 9B is a plan view of the electrode portion of the resistance element and a sectional view of the electrode portion taken along the first direction. In FIG. 9A and FIG. 9B, the polycrystalline silicon layers 16 and 17 and silicide layer 18 of each of the select transistors ST1 and ST2 are collectively shown as an upper conductive film 40. The polycrystalline silicon layers 16 and 17 and silicide layer 18 of the resistance element are collectively shown as an electrode portion 41.

As shown in FIG. 9A and FIG. 9B, the width W1, along the second direction, of the connection portion EI1, provided in each of the select transistors ST1 and ST2, is different from the width W2, along the first direction, of the connection portion EI2, provided in the resistance element. In other words, the width W1 of the short side of the opening in the inter-gate insulating film 15 in the connection portion EI1 is different from the width W2 of the short side of the opening in the inter-gate insulating film 15 in the connection portion EI2. For example, W1<W2.

Furthermore, the contact plugs CP8 and CP9 on the resistance element are arranged in the top surface of the electrode portion 41 so that a region located immediately above the connection portion EI2 is sandwiched between the contact plugs CP8 and CP9. That is, the contact plugs CP8 and CP9 are arranged so as not to overlap the connection portion EI2. In the example in FIG. 9B, the contact plugs CP8 and CP9 are arranged in a direction different from the second direction and the first direction. In other words, the contact plugs CP8 and CP9 are arranged in a direction different from both the longitudinal direction of the resistor portion (polycrystalline silicon layer 14) of the resistance element and the direction orthogonal to the longitudinal direction. Moreover, in other words, the contact plugs are arranged obliquely to the longitudinal direction of the resistor portion of the resistance element and the direction orthogonal to the longitudinal direction. This also applies to the contact plugs CP10 and CP11 provided in the region A3.

### <Method for Manufacturing the NAND Flash Memory 1>

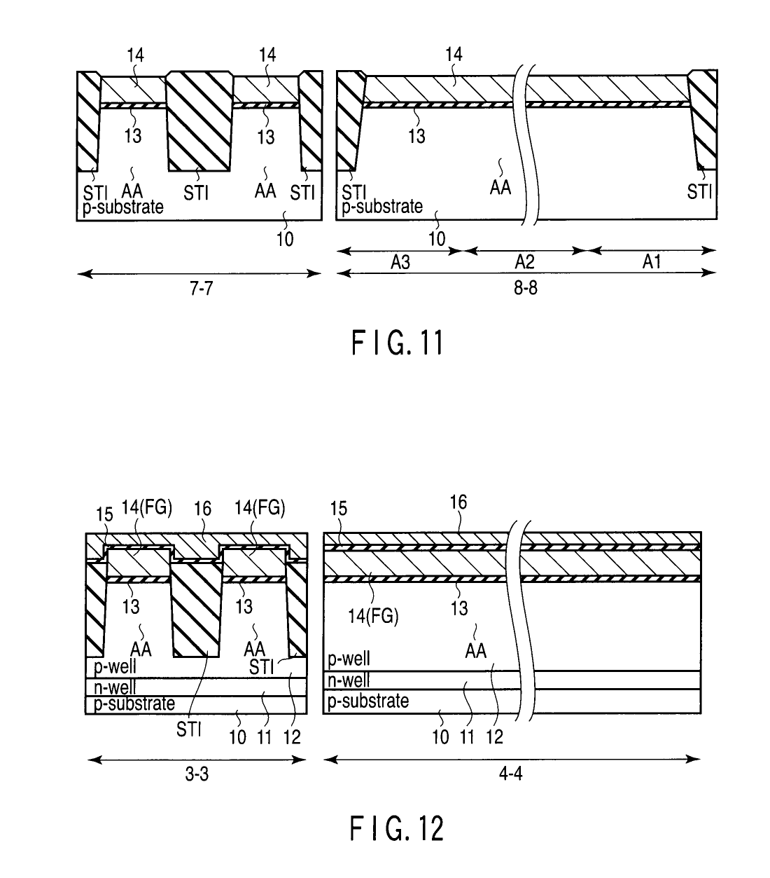

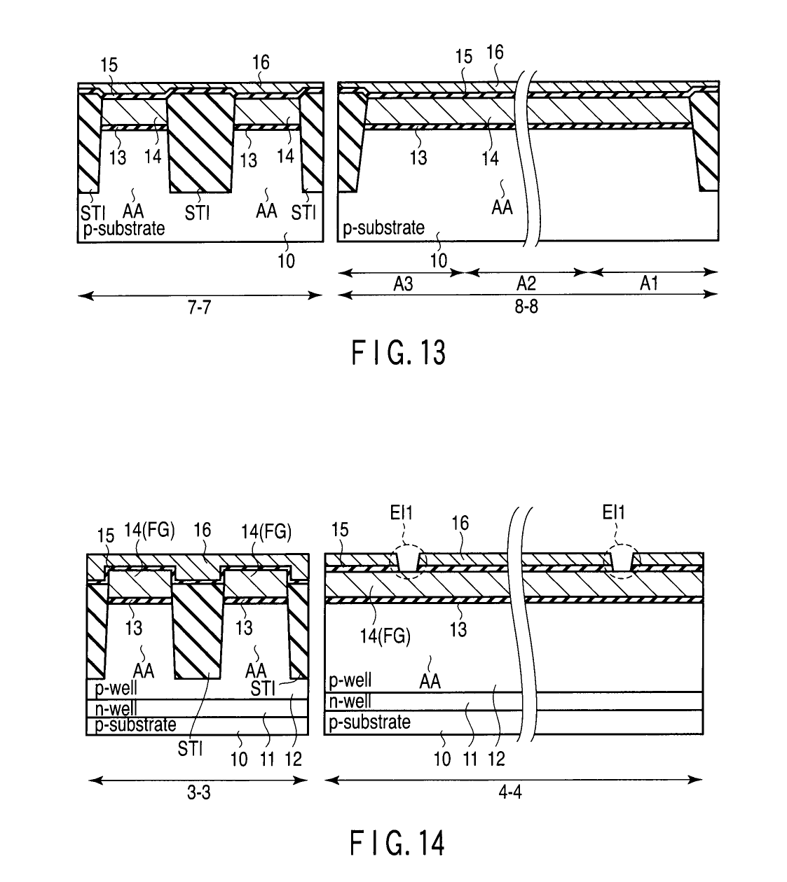

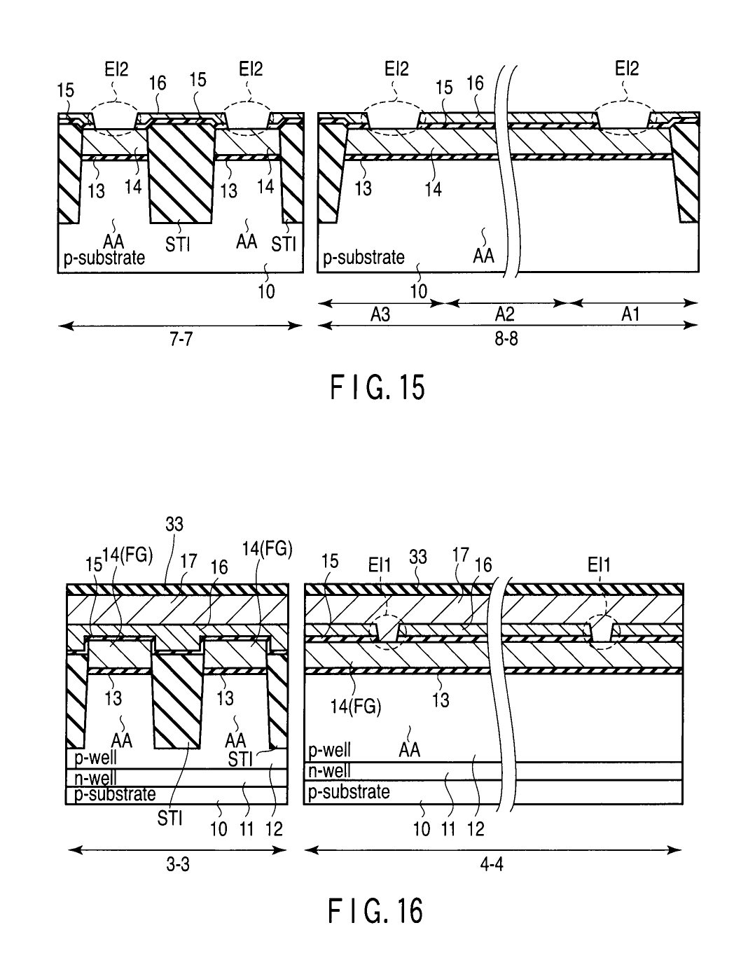

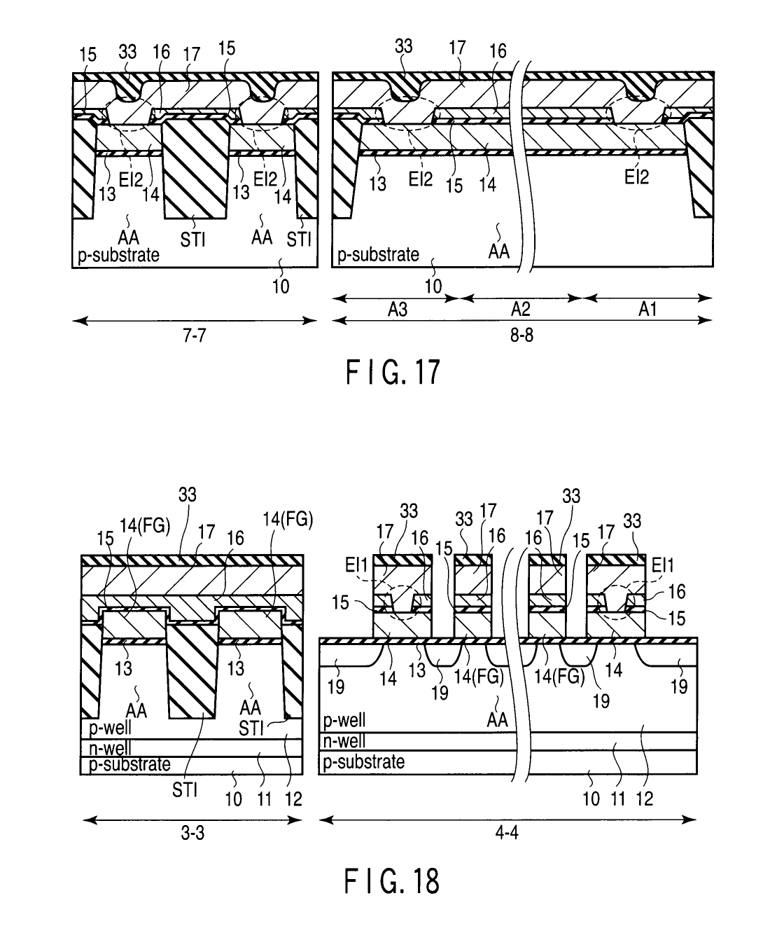

Now, with reference to FIG. 10 to FIG. 27, a method for manufacturing a NAND flash memory configured as described above will be described focusing on the memory cell array and the resistance element. FIG. 10, FIG. 12, FIG. 14, FIG. 16, FIG. 18, FIG. 20, FIG. 22, FIG. 24, and FIG. 26 sequentially show a first step to an eighth step for the NAND flash memory; the figures are sectional views of the memory cell array 1 taken along line 3-3 and 4-4. FIG. 11, FIG. 13, FIG. 15, FIG. 17, FIG. 19, FIG. 21, FIG. 23, FIG. 25, and FIG. 27 sequentially show the first to eighth steps for the NAND flash memory; the figures are sectional views of the resistance element taken along line 7-7 and 8-8. As described above, the memory cell array 2 and the resistance elements in the peripheral circuit 3 are formed on the same p-type semiconductor substrate (silicon substrate) 10.

### <First Step>

First, the first step will be described with reference to FIG. 10 and FIG. 11. As shown in FIG. 10 and FIG. 11, an n-type well region 11 is formed in the top portion of a memory cell array 2 formation region in the p-type semiconductor substrate (silicon substrate) 10 by ion implantation. Moreover, a p-type well region 12 is formed in the surface of the n-type well region 11 by ion implantation.

Subsequently, a gate insulating film 13 as a tunnel oxide film for the memory cell transistor MT is formed on the well region 12 using a silicon oxide film or a silicon oxynitride film. Furthermore, a gate insulating film 13 is formed on the peripheral circuit (resistance element formation region) 3 on the semiconductor substrate 10 using a silicon oxide film or a silicon oxynitride film; the gate insulating film 13 allows the resistance elements to be electrically separated from the semiconductor substrate 10. The gate insulating films 13 in the memory cell transistor MT and resistance element may be formed in the same step or different steps. The materials and film thicknesses of the gate insulating film 13 of the memory cell transistor MT and resistance element may also be the same or different.

Subsequently, a polycrystalline silicon layer 14 is formed on the gate insulating film 13. The polycrystalline silicon layer 14 functions as a charge accumulation layer in the memory cell transistor MT and as a substantial resistor portion in the resistance element. The polycrystalline silicon layer 14 is an n-type semiconductor into which, for example, phosphorous or arsenic, which is an n-type impurity, is doped as a conductive impurity. The polycrystalline silicon layer 14 may be replaced with, for example, a SiGe layer.

Then, a trench is formed in a region as the element isolation region STI. Specifically, the polycrystalline silicon layer 14, the gate insulating film 13, and the semiconductor substrate 10 are sequentially etched. Thus, a trench for forming the element isolation region STI is made in self-alignment with the polycrystalline silicon layer 14.

The width of the trench and the distance between the trenches in the peripheral circuit 3 are sufficiently larger than those in the memory cell array 2. That is, variation of resistance can be reduced by reducing a process variation. Desirably, the element regions AA in the dummy element portions are formed parallel with the resistance elements so as to have the same width so that at least one of the element regions AA is formed adjacent to the resistance element. That is, process variation is reduced by the nonunifomity of a pattern so as to form resistance elements with a more uniform width. This is because a periodic pattern enables a process variation in lithography to be reduced and micro-loading effect to be prevented during etching; the micro-loading effect refers to variation in etching depth or etching side surface taper depending on trench width.

Thereafter, an insulating film (silicon oxide film) is buried in the trench, for example, by an HDP (High Density Plasma) method or an HTO method using a film such as polysilazane which is converted into a silicon oxide film. The surface of the resulting structure is then flattened, for example, by RIE or CMP (Chemical Mechanical Polishing). At this time, the surface of the insulating film in the memory cell array is etched back to set the top surface of the insulating film lower than the surface of the polycrystalline silicon layer 14. On the other hand, the reliability of the resistance elements can be improved by avoiding etching back the insulating film in the resistance element and dummy element. As a result, the element isolation region STI with the insulating film buried in the trench is completed. The configuration shown in FIG. 10 is obtained.

### <Second Step>

Now, the second step will be described with reference to FIG. 12 and FIG. 13. As shown in FIG. 12 and FIG. 13, in the memory cell array 2 and the peripheral circuit 3, an inter-gate insulating film 15 is deposited all over the polycrystalline silicon layer 14; the inter-gate insulating film 15 has a silicon oxide film or a three-layer structure of a silicon oxide film, a silicon nitride film, and a silicon oxide film. A polycrystalline silicon layer 16 is deposited all over the gate insulating film 15.

### <Third Step>

Now, the third step will be described with reference to FIG. 14 and FIG. 15. As shown in FIG. 14 and FIG. 15, connection portions E11 and EI2 are formed by a photolithography technique and anisotropic etching such as RIE. That is, in the memory cell array 2, the polycrystalline silicon layer 16 and the gate insulating film 15 are partly removed from the region in which the select transistor ST1 or ST2 is to be formed. As a result, the connection portion EI1 is formed, with the polycrystalline silicon layer 14 exposed in the connection portion EI1. On the other hand, in the peripheral circuit 3, the polycrystalline silicon layer 16 and the gate insulating film 15 are partly removed from the region in which the region A1 or A3 is to be formed. As a result, the connection EI2 is formed, with the polycrystalline silicon layer 14 exposed in the connection portion EI2. As described above, the short side of the opening, in the memory cell array 2, in which the polycrystalline silicon layer 14 is exposed is smaller than that of the opening, in the peripheral circuit 3, in which the polycrystalline silicon layer 14 is exposed. The opening may not be formed in the dummy element portion.

### <Fourth Step>

Now, the fourth step will be described with reference to FIG. 16 and FIG. 17. As shown in FIG. 16 and FIG. 17, in the memory cell array 2 and the peripheral circuit 3, a polycrystalline silicon layer 17 is deposited on the polycrystalline silicon layer 16 and on the polycrystalline silicon layer 14 exposed in the connection portions E11 and EI2. The polycrystalline silicon layer 17 is an n-type semiconductor into which, for example, phosphorous or arsenic, which is an n-type impurity, is doped as a conductive impurity. The polycrystalline silicon layer 17 is formed in contact with the polycrystalline silicon layer 14 by being filled into the opening in the connection portions EI1 and EI2.

In this case, in the memory cell array 2, the connection portion EI1 has a small opening width. Thus, the top surface of the polycrystalline silicon layer 17 is almost flat. On the other hand, in the peripheral circuit 3, the connection portion EI2 has a large opening width. As described above, the short side of the connection portion EI2 is larger than that of the connection portion EI1. Thus, the top surface of the polycrystalline silicon layer 17 is recessed in a region located immediately above the connection portion EI2. That is, the surface of the polycrystalline silicon layer 17 has a step with a depth at the deepest position almost equal to the sum of the film thicknesses of the gate insulating film 15 and the polycrystalline silicon layer 16.

Subsequently, an insulating film, for example, a silicon nitride film 33, is formed on the polycrystalline silicon layer 17. The silicon nitride film 33 fills the recess in the polycrystalline silicon layer 17, located immediately above the connection portion EI2.

### <Fifth Step>

Now, the fifth step will be described with reference to FIG. 18 and FIG. 19. As shown in FIG. 18 and FIG. 19, in the memory cell array 2, the silicon nitride film 33, the polycrystalline silicon layers 17 and 16, the inter-gate insulating film 15, and the polycrystalline silicon layer 14 are etched in a stripe gate electrode pattern extending along the first direction as shown in FIG. 2. As a result, as shown in FIG. 18 and FIG. 19, the stacked gates of the memory cell transistor MT and the select transistor ST are completed. In this case, the etching is performed such that the connection portion EI1 is included in the stacked gate of each of the select transistors ST1 and ST2.

In the present step, in the peripheral circuit 3, the silicon nitride film 33, the polycrystalline silicon layers 17 and 16, and the inter-gate insulating film 15 are etched by the photolithography technique and the anisotropic etching such as RIE. The silicon nitride film 33, the polycrystalline silicon layers 17 and 16, and the inter-gate insulating film 15 are processed into a stripe shape extending along the second direction similarly to the element region AA so as to cover the element region AA. The resulting shape projects outward from the end of the element region AA as shown in FIG. 6. Thus, the layers 15 to 17 and 33 completely cover the top surface of the polycrystalline silicon layer 14. In the present step, the resistance element and the dummy element are sufficiently wider than the memory cell transistor MT and thus may not be subjected to lithography and etching at an accuracy and a resolution similar to those for the memory cell array 2. That is, when the photolithography and etching of the memory cell array is performed in a separate step, it is possible to use inexpensive lithography equipment.

The silicon nitride film 33, polycrystalline silicon layers 17 and 16, and inter-gate insulating film 15 in the peripheral circuit 3 are etched by the photolithography technique and RIE. This etching is performed so as to remove the layers 16, 17, and 33 along the first direction in FIG. 6. As a result, each of the layers 16, 17, and 33 are separated into the regions A1, A2, and A3 to complete the resistance element. The regions A1, A2, and A3 are electrically separated from one another by trenches 43 formed by the etching.

In this case, the etching is performed such that the trench 43 is positioned closer to the center of the element region AA (or layer 14) in second direction than the connection portion EI2. That is, each of the regions A1 and A3 completely covers the connection portion EI2 in this etching. Furthermore, the layers 17 and 16 belonging to the region A2 are not in contact with the connection portion EI2 and can thus be allowed to float electrically.

In the present step, the inter-gate insulating film 15 may be left at the bottom of the trench 43. To achieve this, the etching condition in which an etching speed of the silicon oxide is lower than that of the polycrystalline silicon may be applied. This enables part of the polycrystalline silicon layer 14 to be prevented from being etched at the bottom of the trench 43. That is, a reducing the area of the resistance element functioning as a substantial resistor portion can be prevented. Thus, more precise sharp of resistance elements can be realized.

Thereafter, p-type impurities are ion-implanted into the memory cell array 2 using the stacked gate structure as a mask. As a result, an impurity diffusion layer 19 is formed in the surface of the well region 12. Thus, the memory cell transistors MT and the select transistors ST1 and ST2 are completed.

### <Sixth Step>

Now, the sixth step will be described with reference to FIG. 20 and FIG. 21. As shown in FIG. 20 and FIG. 21, an interlayer insulating film 34 is formed on the semiconductor substrate 10 so as to cover the memory cell transistors, the select transistors ST1 and ST2, and the resistance elements. Thereafter, for example, the interlayer insulating film 34 is polished by CMP or the like using the silicon nitride film 33 as a stopper. The height of the surface of the interlayer insulating film 34 is adjusted to that of the surface of the silicon nitride film 33. That is, in the memory cell array 2, the region between the adjacent stacked gate structures is filled with the interlayer insulating film 34. In the peripheral circuit 3, the region between the adjacent electrodes is filled with the interlayer insulating film 34.

### <Seventh Step>

Now, the seventh step will be described with reference to FIG. 22 and FIG. 23. As shown in FIG. 22 and FIG. 23, the silicon nitride film 33 is removed by anisotropic etching, for example, RIE. Thus, the surface of the polycrystalline silicon layer 17 is exposed in the memory cell array 2 and the peripheral circuit 3. At the same time, the surface of the interlayer insulating film 34 is set lower than that of the polycrystalline silicon layer 17. Here, in the regions A1 and A3 of the resistance element, the silicon nitride film buried in the recess (see FIG. 21) in the surface of the polycrystalline silicon layer 17 partly remains. Overetching is expected to enable the silicon nitride film in the recess to be removed but poses the following problems.

The overetching for removing the silicon nitride film 33 causes the surface of the interlayer insulating film 34, etched simultaneously with the silicon nitride film 33, to be located at an excessively deep position. As a result, more of the polycrystalline silicon layer 17 is silicided in the next step (eighth step), resulting in, for example, more severe leakage between the adjacent word lines WL.

### <Eighth Step>

Now, the eighth step will be described with reference to FIG. 24 and FIG. 25. As shown in FIG. 24 and FIG. 25, a metal layer such as tungsten is formed all over the surface of the resulting structure. silicide the surface of the polycrystalline silicon layer 17 by thermal treatment. Thus, a silicide layer 18 is formed. In this case, the silicon nitride film 33 remains in the recess in the polycrystalline silicon layer 17 in each of the regions A1 and A3 of the resistance element. This inhibits the polycrystalline silicon layer 17 from contacting the metal layer, thus preventing the formation of a silicide layer 18. That is, the silicide layer 18 is formed so as to surround the silicon nitride film 33. In the present step, all of the polycrystalline silicon layer 17 may be silicided.

### <Ninth Step>

Now, the ninth step will be described with reference to FIG. 26 and FIG. 27. As shown in FIG. 26 and FIG. 27, an interlayer insulating film 20 is formed on the semiconductor substrate 10 so as to cover the memory cell transistors MT, the select transistors ST1 and ST2, and the resistance elements. The interlayer insulating film 20 is formed of, for example, silicate glass such as BPSG (Boron Phosphorous Silicate Glass), BSG (Boron Silicate Glass), or PSG (Phosphorous Silicate Glass), or HSQ or MSG.

Subsequently, in the memory cell array 2, contact plugs CP2 and CP5 are formed in the interlayer insulating film 20; the contact plug CP2 reaches the source of the select transistor ST2, and the contact plug CP5 reaches the drain of the select transistor ST1. In the peripheral circuit 3, contact plugs CP8 to CP11 reaching the silicide layer 18 in the electrode portion of the resistance element are formed in the interlayer insulating film 20. As described above, the contact plugs CP8 to CP11 are formed so as not to immediately above the connection portion EI2. In other words, bottom of the contact plugs CP8 to CP11 are not completely formed on the silicon nitride film 33 but bottoms of part of the contact plugs CP8 to CP11 are formed on the silicide layer 18.

Thereafter, required interlayer insulating films, metal wiring layers, contact plugs, and the like are formed to complete the NAND flash memory 1 shown in FIG. 2 to FIG. 8.

### <Effects>

The NAND flash memory according to the present embodiment exerts effects (1) and (2) described below.

(1) The reliability of the resistance element can be improved.

As described above in the embodiment, the connection portion EI2 of the resistance element is formed by etching the polycrystalline silicon layer 16 and the inter-gate insulating film 15. Thereafter, a cleaning process is carried out, and a polycrystalline silicon layer 17 is then formed. In this case, a native oxide film or etching residues may be present on the surface of the polycrystalline silicon layer 14 exposed by etching. Then, even after the formation of the polycrystalline silicon layer 17, the native oxide film or etching residues function electrically as a resistor. This increases the electric resistance (hereinafter referred to as the EI resistance) of the contact portion between the polycrystalline silicon layers 14 and 17.

In particular, the native oxide film is unavoidably generated, and controlling the film thickness of the native oxide film is very difficult. Thus, the native oxide film is considered to be a major factor varying the resistance value of the resistance element. A decrease in the resistance value of the resistance element enhances the impact of the EI resistance. This is because for a resistance element offering a high resistance, the ratio of the E1 resistance to the major resistance component (the resistance of the polycrystalline silicon layer 14, serving as the resistor portion) is low.

On the other hand, to improve the precision of the resistance element, it is important to inhibit possible variation rather than reducing the resistance value of the EI resistance. This is because even if the EI resistance exhibits a slightly large resistance value, the resistance element may be designed with the resistance value taken into account the slightly large resistance value itself that is stable. However, an effective technique for inhibiting variation is eventually to reduce the resistance value itself. Furthermore, forming a plurality of narrow connection portions E12 is very difficult in connection with photolithography or processing and thus unsuitable for shrinking.

Thus, in the present embodiment, the connection portion EI2 of the resistance element is wider than in the conventional art. This enables a reduction in the resistance value of the contact portion between the polycrystalline silicon layers 14 and 17 in the connection portion EI2 and thus in variation in the resistance value of the EI resistance. Inhibiting the variation further enables a variation in the resistance value of the whole resistance element, thus improving the reliability of the resistance element. The improved reliability of the resistance element contributes to improving the reliability of the whole NAND flash memory 1.

While the width of the connection portion EI2 is increased, the width of the connection portion EI1 of each of the select transistors ST1 and ST2 is not increased. This is because each of the select transistors ST1 and ST2 has a small gate electrode width (small channel length) in order to meet the demand for shrinking, so that forming a wide connection portion EI1 in the narrow gate electrode is extremely difficult in connection with overlapping in lithography or with processing. As a result, the connection portions EI1 and EI2 have different widths. In other words, the contact area between the polycrystalline silicon layers 14 and 17 in the connection portion EI2 in each of the electrode portions of the resistance element is larger than that in the connection portion EI1 of each of the select transistors ST1 and ST2. When the connection portion EI1 of each of the select transistors ST1 and ST2 has the same size as that in the conventional art, the above-described effects are exerted without a complicating the manufacturing process of the NAND flash memory 1.

(2) The resistance element and the contact plug stably contact each other.

When the width of the connection portion EI2 is increased as described above in (1), then, for example, as shown in FIG. 17, the step in the connection portion EI2 may fail to be completely filled with the polycrystalline silicon layer 17. A recess (slit or step) may thus be created in the surface of the polycrystalline silicon layer 17. For example, when the width of the connection portion EI2 is at least double the film thickness of the polycrystalline silicon layer 17, completely filling the step with the polycrystalline silicon layer 17 is difficult.

Such a recess may pose the following problems. That is, the silicon nitride film 33, serving as a cap layer, is formed on the top surface of the polycrystalline silicon layer 17. The recess in the surface of the polycrystalline silicon layer 17 is filled with the silicon nitride film 33 (see FIG. 17). Thereafter, before the formation of the silicide layer 18, the silicon nitride film 33 is etched. However, the silicon nitride film 33 in the recess may remain unetched (see FIG. 23). As a result, the contact plugs CP8 to CP11, otherwise formed on the electrode portion of the resistance element, may be formed on the silicon nitride film 33. Then, electrically connecting the contact plugs CP8 to CP11 to the resistance element may be difficult.

However, in the configuration according to the present embodiment, the contact plugs CP8 to CP11 are arranged on the electrode portion 41 so that the region located immediately above the connection portion EI2 is sandwiched between the contact plugs. That is, the bottoms of the contact plugs CP8 to CP11 are completely arranged so as not to overlap the connection portion EI2. Thus, at least a part of the bottom of the contact plugs CP8 to CP11 can be formed on the silicide layer 18 and not on the silicon nitride film 33, allowing the resistance element and the contact plugs to be electrically connected together. In other word, other part of the contact plugs CP8 to CP11 can be formed on the silicon nitride film 33.

Further more, all the bottom of the contact plugs CP8 to CP11 can be formed on the silicide layer 18 and not on the silicon nitride film 33, allowing the resistance element and the contact plugs to be electrically connected together stably. In other words, the electrode portion 41 has a recess at its surface. The region of the surface of the second conductive film contacted by the contact plug is positioned higher than a bottom surface of the recess.

In this case, for example, as shown in FIG. 9, the plurality of contact plugs formed on each of the electrode portions are preferably arranged so that the connection portion EI2 is sandwiched between the contact plugs along a direction that is oblique to both the longitudinal direction of the resistor portion of the resistance element and the direction orthogonal to the longitudinal direction. This is because this arrangement allows the distance between the plurality of adjacent contact plugs to be maximized in the direction (the first direction in FIG. 6) orthogonal to the longitudinal direction of the resistance element. This in turn eliminates the need to increase the width of the resistance element in the direction orthogonal to the longitudinal direction of the resistor portion more than required.

Furthermore, the contact plug can be formed on the connection portion EI1 of each of the select gate lines SGD and SGS in the shunt portion. This is because the connection portion EI1 is narrow, so that no recess is created in the surface of the polycrystalline silicon layer 17. Precisely speaking, a recess is created in the surface of the crystal silicon layer 17, but during the formation of the silicide layer 18, the silicon nitride film 33 can be removed from the recess by etching the silicon nitride film 33. As a result, the connection portion EI1 is allowed to exist in the shunt region similar to other region in memory cell array, thus allowing the improvement of a processing margin during the formation of the connection portion EI1 in the third step.

### Second Embodiment

Now, a semiconductor device according to a second embodiment of the present invention will be described. The present embodiment relates to the arrangement and shape of the connection portion EI2 of the resistance element in the above-described first embodiment and the manner of arranging the contact plugs CP8 to CP11 with respect to the connection potion EI2. Only differences from the first embodiment will be described below.

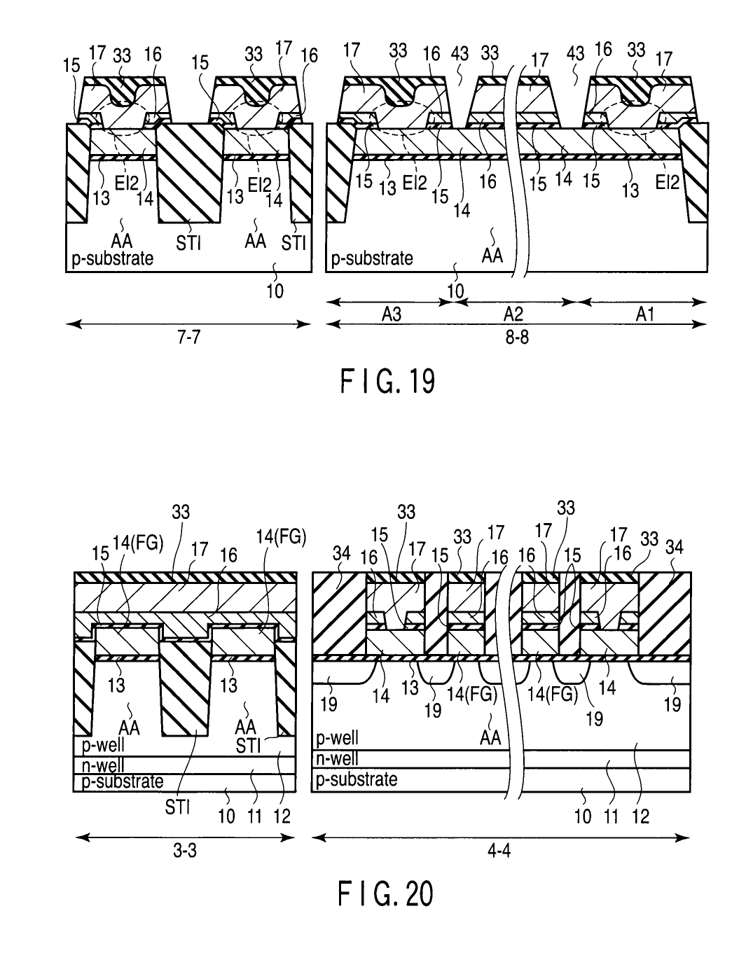

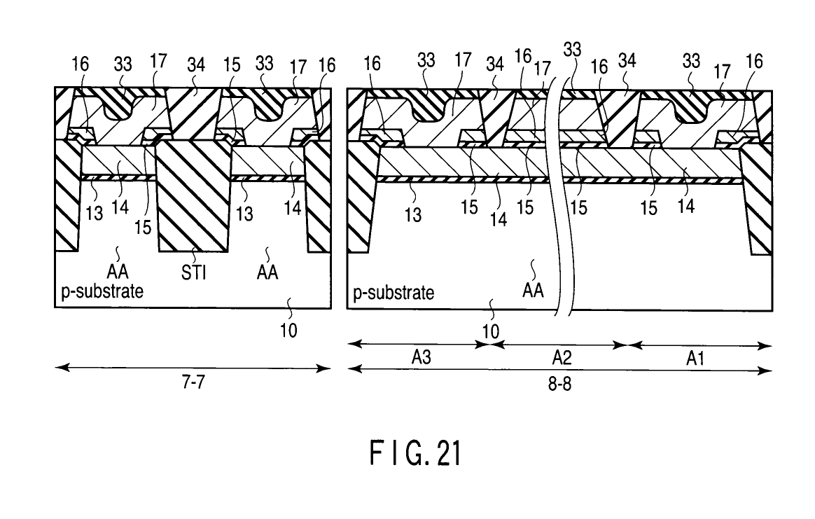

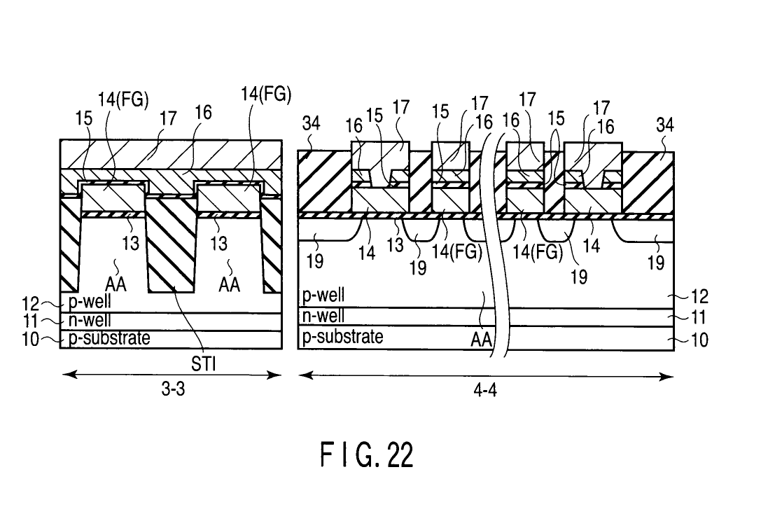

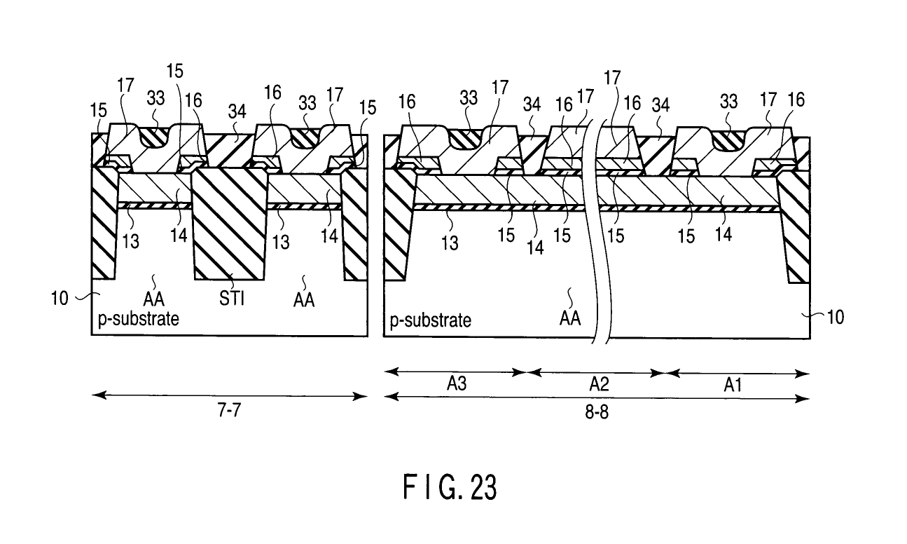

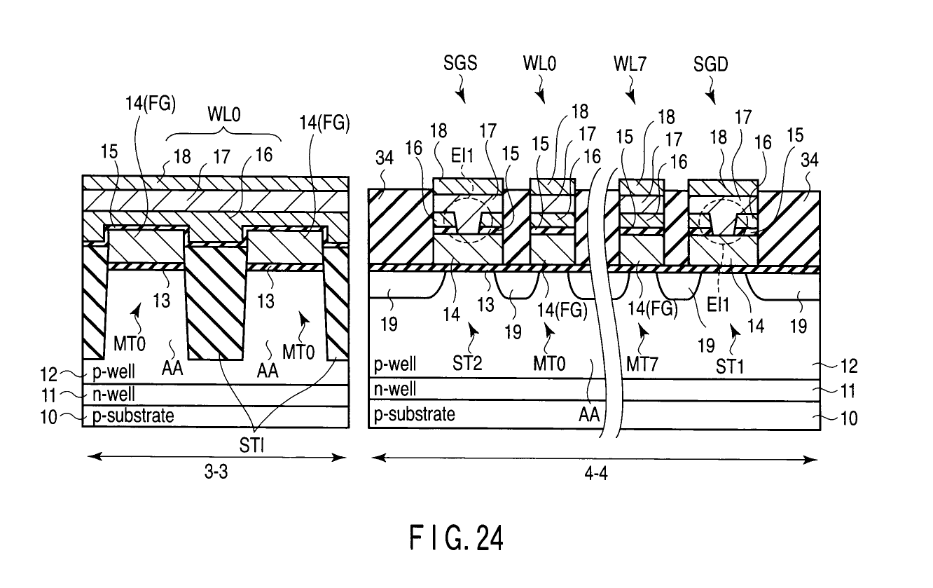

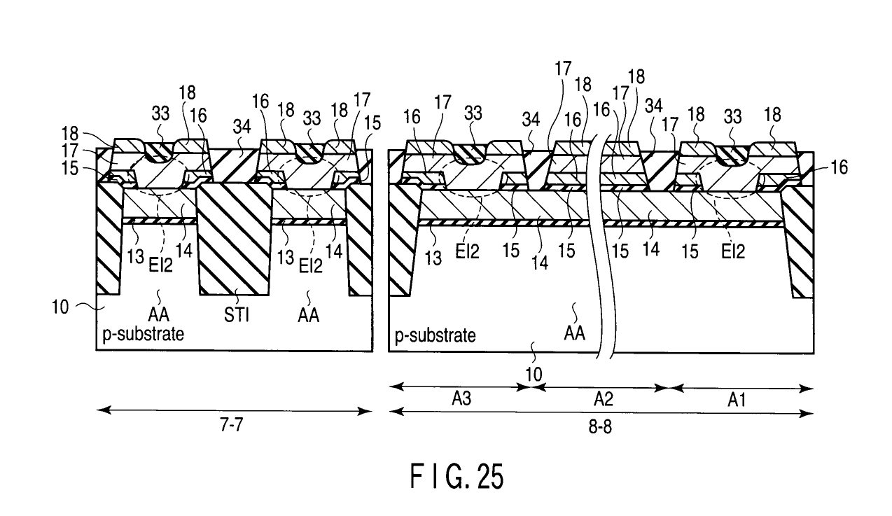

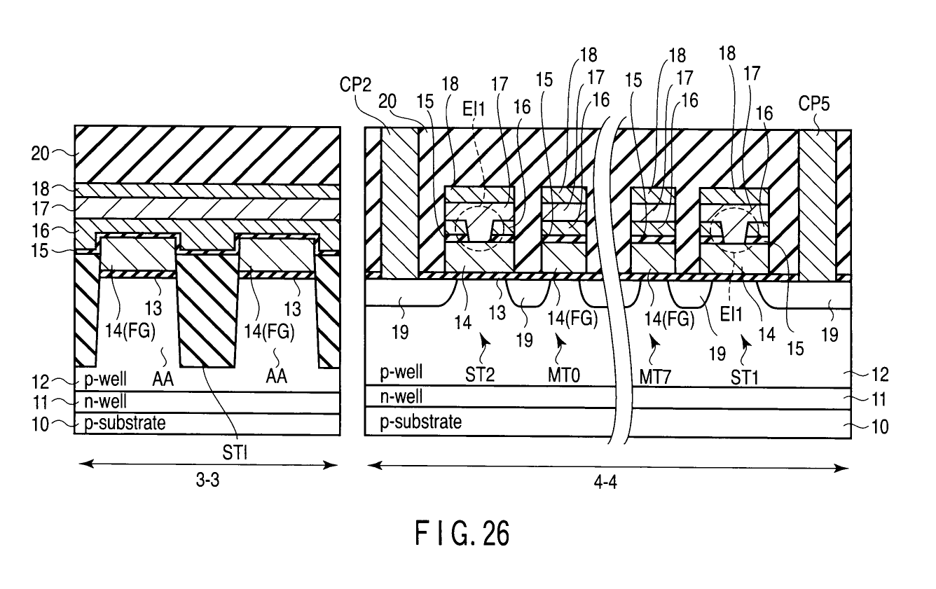

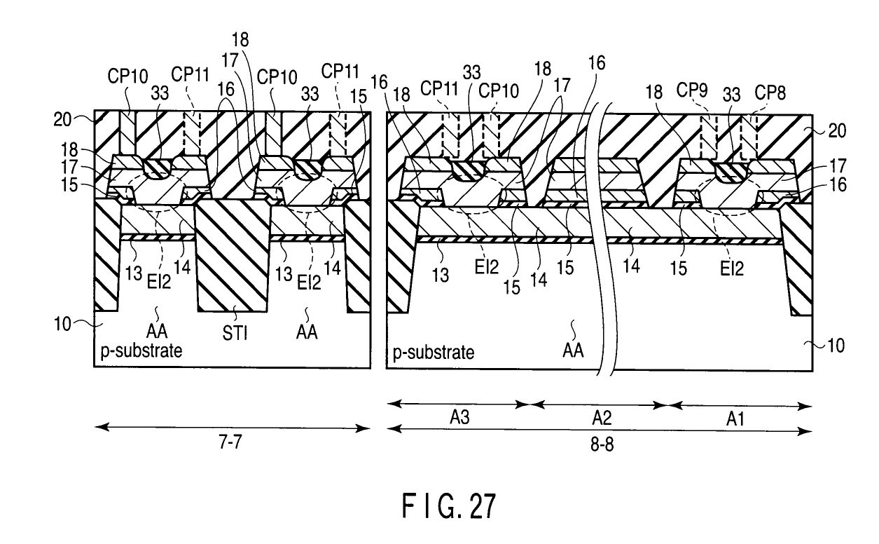

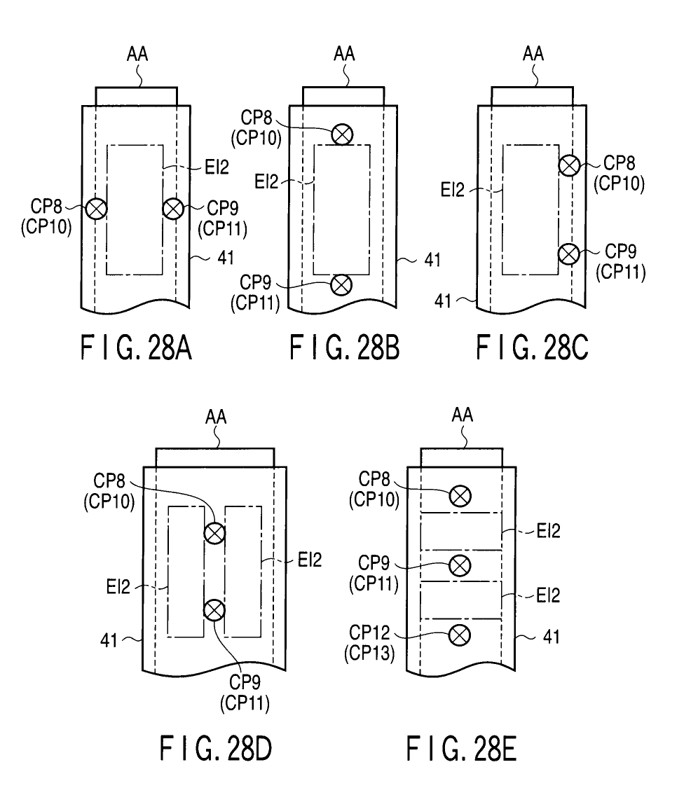

FIG. 28A to FIG. 28E are plan views of regions A1 and A3 of a resistance element according to the present embodiment. FIG. 28A to FIG. 28E particularly show the connection portion EI2 and the contact plugs CP8 to CP11. In FIG. 28A to FIG. 28E, parenthesized reference numerals indicate a pattern for the region A3.

As shown in FIG. 28A, the contact plug CP8 (CP10) and the contact plug CP9 (CP11) may be arranged such that the connection portion EI2 is sandwiched between the contact plugs CP8 (CP10) and CP9 (CP11) along the direction (the first direction in FIG. 6) orthogonal to the longitudinal direction of the resistance element.

Alternatively, as shown in FIG. 28B, the contact plug CP8 (CP10) and the contact plug CP9 (CP11) may be arranged such that the connection portion EI2 is sandwiched between the contact plugs CP8 (CP10) and CP9 (CP11) in the direction (the second direction in FIG. 6) along the longitudinal direction of the resistance element.

Alternatively, as shown in FIG. 28C, the contact plug CP8 (CP10) and the contact plug CP9 (CP11) may be arranged in the direction (the second direction in FIG. 6) along the longitudinal direction of the resistance element and along one side of the connection portion EI2. In this case, the contact plug CP8 (CP10) and the contact plug CP9 (CP11) do not sandwich the connection portion EI2.

Alternatively, a plurality of the connection portions EI2 may be provided for each electrode portion. This will be described with reference to FIG. 28D and FIG. 28E. As shown in FIG. 28D, two connection portions EI2 are formed along the direction (the first direction in FIG. 6) orthogonal to the longitudinal direction of the resistance element. The contact plug CP8 (CP10) and the contact plug CP9 (CP11) are arranged on the silicide layer 18 between two connection portions EI2 along the longitudinal direction of the resistance element.

Alternatively, as shown in FIG. 28E, two connection portions EI2 may be formed along the direction (the first direction in FIG. 6) orthogonal to the longitudinal direction of the resistance element. Then, three contact plugs CP8 (CP10), CP9 (CP11), and CP12 (CP13) may be arranged such that each of the connection portions EI2 is sandwiched between the contact plugs.

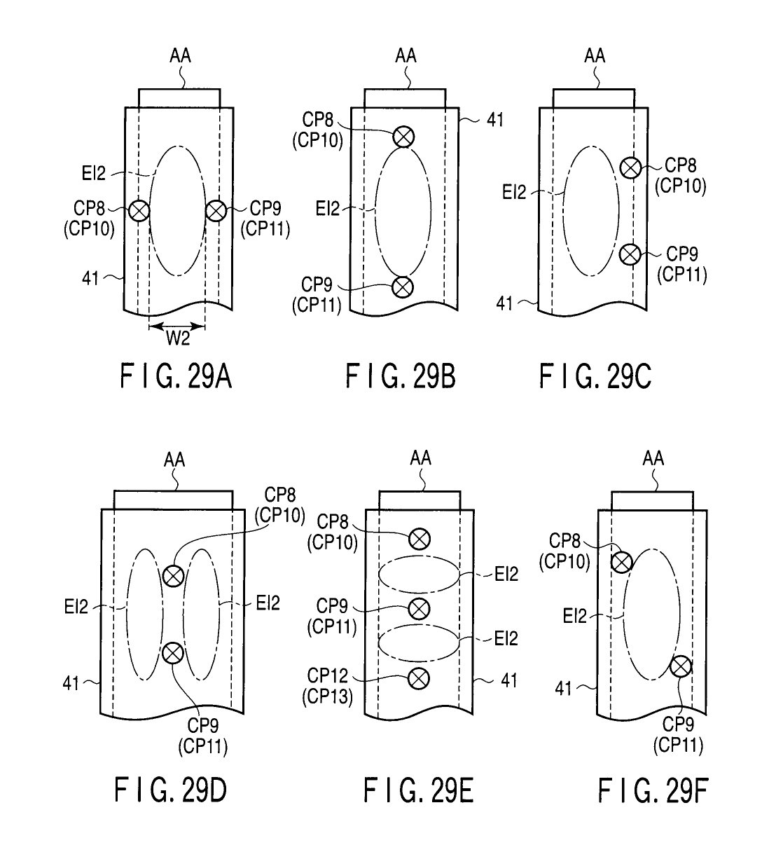

Another example is shown in FIG. 29A to FIG. 29F. Like FIG. 28A to FIG. 28E, FIG. 29A to FIG. 29F are plan views of the regions A1 and A3 in the resistance element according to the present embodiment. As shown in FIG. 29A to FIG. 29E, in FIG. 28A to FIG. 28E described above, the connection portion EI2 may be shaped like an ellipse instead of a rectangle. Furthermore, even in the arrangement in FIG. 9 described in the first embodiment, the connection portion EI2 may be shaped like an ellipse as shown in FIG. 29A. This also applies to the select transistors ST1 and ST2. In this case, the width (minor diameter) W1 of the minor axis direction of the connection portion EI1 (the opening in the inter-gate insulating film 15 in the connection portion EI1) is different from the width (minor diameter) W2 of the minor axis direction of the connection portion EI2 (the opening in the inter-gate insulating film 15 in the connection portion EI2). For example, W1<W2.

The configuration of the connection portion EI1 and the arrangement of the contact plugs CP8 to CP11 may be as described above. In this case, effects similar to those in the first embodiment are exerted.

In the example shown in FIG. 28A, FIG. 28C, FIG. 29A and FIG. 29C, the contact plugs CP8 to CP11 may be formed at a boundary between the element region AA and the element isolation region STI.

The embodiments of the present invention are not limited to those described above. For example, in the configurations described in the first and second embodiment, the silicide layer 18 may be omitted. In this case, the contact plugs CP8 to CP11 are formed on the polycrystalline silicon layer 17. However, the silicide layer 18 can function as a stopper for RIE during the formation of contact holes for forming the contact plugs CP8 to CP11. Thus, the silicide layer 18 is preferably formed.

Alternatively, provided that the recess in the surface of the polycrystalline silicon layer 17 is small and only a small amount of silicon nitride film 33 remains, the contact plugs CP8 to CP11 may partly overlap the connection portion EI2. That is, it is only necessary to avoid forming the contact plugs CP8 to CP10 on the silicon nitride film 33.

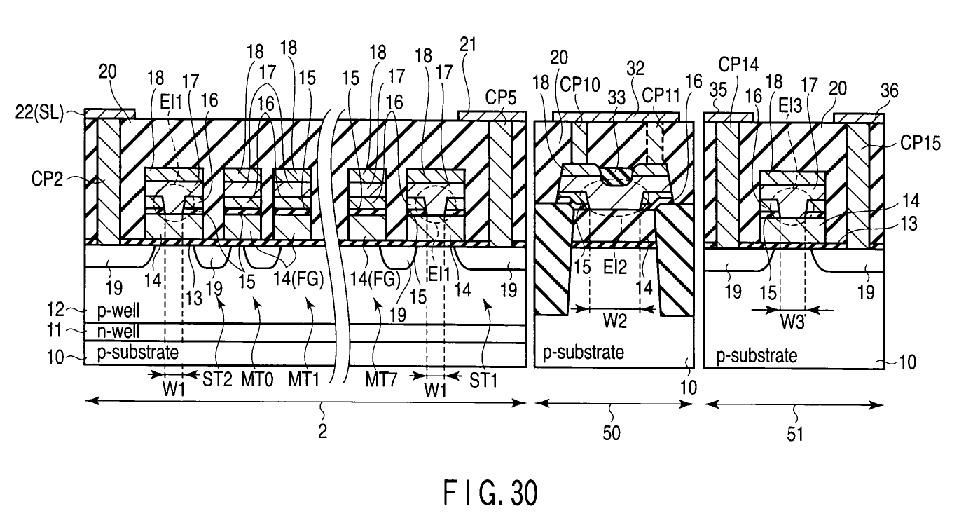

Moreover, in the above-described embodiments, the resistance element is configured similarly to the select transistors ST1 and ST2 by way of example. However, the MOS transistors (peripheral transistors) included in the peripheral circuit 3 may be configured similarly to the select transistors ST1 and ST2. FIG. 30 is a sectional view of the NAND flash memory 1 in the present example, showing the memory cell array 2, a resistance element 50, and a peripheral transistor 51.

As shown in FIG. 30, the peripheral transistor 51 is configured similarly to the select transistors ST1 and ST2. In a connection portion EI3 of the peripheral transistor, the inter-gate insulating film 15 and the polycrystalline silicon layer 16 are partly removed so as to connect the polycrystalline silicon layers 14 and 17 together. The short side W3 of the opening in the inter-gate insulating film 15 in the connection portion EI13 is different from the width W2 in the connection portion EI2. For example, W3<W2 and W3>W1.

Moreover, the inter-gate insulating film 15 may be TiO₂, HfO, Al₂O₃, HfAlO, HfSiO, a tantalum oxide film, strontium titanate, barium titanate, lead zirconium titanate, a silicon oxynitride film, a silicon oxide film, a silicon nitride film, or stacked film of any of these films.

In the examples described in the embodiments, the p-type silicon substrate is used as the semiconductor substrate 10. However, an n-type silicon substrate or an SOI substrate may be used in place of the p-type silicon substrate. Alternatively, any other substrate may be used which is composed of a single crystal containing silicon, such as a SiGe mixed crystal or an SiGeC mixed crystal. Moreover, TiSi, NiSi, CoSi, TaSi, WSi, MoSi, or the like may be used as a material for the silicide layer 18. Furthermore, instead of the polycrystalline silicon layers 14, 16, and 17, amorphous silicon, amorphous SiGe, amorphous SiGeC, or a stacked structure of any of these layers may be used.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a resistance element including:
a first conductive film formed on a semiconductor substrate with a first insulating film interposed therebetween;
a second insulating film formed on the first conductive film;
a second conductive film formed on the second insulating film;
a first connection portion in which the second insulating film is removed and which connects the first conductive film and the second conductive film together; and
a plurality of contact plugs formed on the second conductive film, the plurality of contact plugs being arranged such that a region located on the second conductive film and immediately above the connection portion is sandwiched between the contact plugs.

2. The device according to claim 1, wherein the contact plugs are arranged in a top surface of the second conductive film in a direction different from a longitudinal direction of the first conductive film and a direction orthogonal to the longitudinal direction.

3. The device according to claim 1, further comprising a silicide layer formed on the second conductive film excluding at least a region immediately above the first connection portion.

4. The device according to claim 3, wherein the contact plugs are formed on the silicide layer.

5. The device according to claim 1, wherein the second conductive film has a recess at a surface, and a region of the surface of the second conductive film which is contacted by the contact plug is positioned higher than a bottom surface of the recess.

6. The device according to claim 2, wherein a plurality of the resistance elements are arranged,
the plurality of resistance elements are arranged adjacent to one another in the direction orthogonal to the longitudinal direction, and
the contact plugs on each of the resistance element are linearly-arranged in the direction orthogonal to the longitudinal direction.

7. A semiconductor device comprising:
a resistance element having a first conductive film formed on a first region of a semiconductor substrate with a first insulating film interposed therebetween, a second insulating film formed on the first conductive film, a second conductive film formed on the second insulating film, and a first connection portion in which the second insulating film is removed to connect the first conductive film and the second conductive film together; and
a MOS transistor having a stacked gate including a third conductive film formed on a second region of the semiconductor substrate with a gate insulating film interposed therebetween, a third insulating film formed on the third conductive film, a fourth conductive film formed on the third insulating film, and a second connection portion in which the third insulating film is removed to connect the third conductive film and the fourth conductive film together, a short side or a minor diameter of the first connection portion being different from that of the second connection portion.

8. The device according to claim 7, further comprising a plurality of first contact plugs formed on the second conductive film,
wherein the plurality of first contact plugs are arranged such that a region located on the second conductive film and immediately above the connection portion is sandwiched between the first contact plugs, and
the plurality of first contact plugs are arranged in a top surface of the second conductive film in a direction different from a longitudinal direction of the first conductive film and a direction orthogonal to the longitudinal direction.

9. The device according to claim 8, further comprising a silicide layer formed on the second conductive film excluding at least a region immediately above the first connection portion.

10. The device according to claim 9, wherein the first contact plugs are formed on the silicide layer.

11. The device according to claim 8, wherein the second conductive film has a recess at a surface, and the recess is positioned immediately above the first connection portion.

12. The device according to claim 7, further comprising a plurality of memory cell transistors formed on the semiconductor substrate and each comprising a stacked gate including a charge accumulation layer and a control gate, and
wherein current paths of the plurality of memory cell transistors are connected together in series, and one end of the series connection is connected to one end of a current path of the MOS transistor.

13. The device according to claim 7, wherein a short side or a minor diameter of the first connection portion is larger than that of the second connection portion.

14. The device according to claim 7, further comprising a second contact plug formed on the fourth conductive film,
wherein the second contact plug is located immediately above the second connection portion.

15. A semiconductor device comprising:
a first conductive film formed on a semiconductor substrate with a first insulating film interposed therebetween;
a second insulating film formed on the first conductive film;
a second conductive film formed on the second insulating film;
a connection portion in which the second insulating film is removed and which connects the first conductive film and the second conductive film together; and
a plurality of contact plugs formed on the second conductive film excluding a region immediately above the connection portion.

16. The device according to claim 15, further comprising a silicide layer formed on the second conductive film excluding at least a region immediately above the first connection portion.

17. The device according to claim 16, wherein the contact plugs are formed on the silicide layer.

18. The device according to claim 15, wherein the second conductive film has a recess at a surface, and a region of the surface of the second conductive film which is contacted by the contact plug is positioned higher than a bottom surface of the recess.

19. The device according to claim 15, wherein the first conductive film is formed on an element region,
the element region is adjacent to an element isolation region, and
each of the contact plugs is located at a boundary between the element region and the element isolation region.

20. The device according to claim 15, wherein the connection portion is elliptical.
